(19) United States
(12) Patent Application Publication
(10) Pub. No.: US 2025/0257446 A1
(43) Pub. Date: Aug. 14, 2025

(54) FILM-FORMING METHOD AND SUBSTRATE-PROCESSING DEVICE

(71) Applicant: Tokyo Electron Limited, Tokyo (JP)

(72) Inventors: Takashi FUSE, Nirasaki City, Yamanashi (JP); Shuji AZUMO, Nirasaki City, Yamanashi (JP)

(21) Appl. No.: 18/857,016

(22) PCT Filed: Apr. 11, 2023
(86) PCT No.: PCT/JP2023/014772

§ 371 Date: Oct. 15, 2024

(30) Foreign Application Priority Data
Apr. 22, 2022 (JP) 2022-071107

(51) Int. Cl. C23C 16/04; C23C 16/455; C23C 16/52

(52) U.S. Cl. CPC C23C 16/04; C23C 16/45534; C23C 16/45553; C23C 16/52

(57) ABSTRACT

Provided are a film forming method and a substrate processing apparatus which improve selectivity when selectively forming an insulating film in a desired area using a self-assembled monolayer. The method includes: preparing a substrate having a metal film formed on a surface of a first area and a first insulating film formed on a surface of a second area; forming a self-assembled monolayer of an organic compound in the first area by supplying, to a surface of the substrate, a gas containing the organic compound having a chain portion, a first functional group provided at one end of the chain portion, and a second functional group provided at a remaining end of the chain portion; forming a second insulating film in the second area by supplying a precursor gas and a reaction gas to the surface of the substrate; and removing the self-assembled monolayer formed in the first area.

### TECHNICAL FIELD

The present disclosure relates to a film forming method and a substrate processing apparatus.

### BACKGROUND

Patent Document 1 discloses a film forming method including: preparing a substrate having a metal layer of a first metal formed on a surface of a first area and an insulating layer formed on a surface of a second area; forming a self-assembled film on a surface of the metal layer by supplying a raw material gas for the self-assembled film; after forming the self-assembled film, forming a second metal oxide film on the insulating layer through atomic layer deposition by repeating supplying a precursor gas containing the second metal and supplying an oxidizing gas; and reducing an oxide film of the first metal formed on the surface of the first metal by supplying a reducing gas after the supply of the oxidizing gas and before the supply of the precursor gas.

### PRIOR ART DOCUMENT

### Patent Document

Patent Document 1: Japanese Laid-Open Patent Publication No. 2021-125607

### SUMMARY

The present disclosure provides a film forming method and a substrate processing apparatus that improve selectivity when selectively forming an insulating film in a desired area using a self-assembled monolayer.

According to one embodiment of the present disclosure, a film forming method includes: preparing a substrate having a metal film formed on a surface of a first area and a first insulating film formed on a surface of a second area; forming a self-assembled monolayer of an organic compound in the first area by supplying, to a surface of the substrate, a gas containing the organic compound having a chain portion, a first functional group provided at one end of the chain portion, and a second functional group provided at a remaining end of the chain portion; forming a second insulating film in the second area by supplying a precursor gas and a reaction gas to the surface of the substrate; and removing the self-assembled monolayer formed in the first area.

According to the present disclosure, it is possible to provide a film forming method and a substrate processing apparatus that improve selectivity when selectively forming an insulating film in a desired area using a self-assembled monolayer.

### BRIEF DESCRIPTION OF DRAWINGS

FIG. 1 is a schematic cross-sectional view illustrating an example of a film forming apparatus according to an embodiment.

FIG. 2 is a flowchart illustrating an example of a film forming method.

FIG. 3A is an example of a cross-sectional schematic diagram illustrating a state of a substrate in each operation.

FIG. 3B is an example of a cross-sectional schematic diagram illustrating a state of the substrate in each operation.

FIG. 3C is an example of a cross-sectional schematic diagram illustrating a state of the substrate in each operation.

FIG. 3D is an example of a cross-sectional schematic diagram illustrating a state of the substrate in each operation.

FIG. 3E is an example of a cross-sectional schematic diagram illustrating a state of the substrate in each operation.

FIG. 3F is an example of a cross-sectional schematic diagram illustrating a state of the substrate in each operation.

FIG. 4 is an example of a cross-sectional schematic diagram illustrating a self-assembled film according to an embodiment.

FIG. 5 is an example of a cross-sectional schematic diagram illustrating a self-assembled film according to Reference Example.

### DETAILED DESCRIPTION

Hereinafter, non-limiting exemplary embodiments of the present disclosure will be described with reference to the accompanying drawings. Among all the accompanying drawings, the same or corresponding members or components will be denoted by the same or corresponding reference numerals, and redundant descriptions thereof will be omitted.

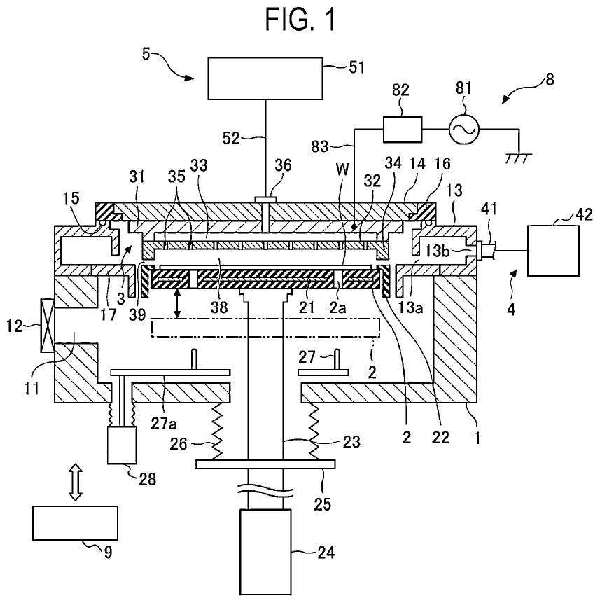

An example of a film forming apparatus according to an embodiment will be described with reference to FIG. 1. FIG. 1 is a schematic cross-sectional view illustrating an example of the film forming apparatus according to an embodiment. The film forming apparatus includes a processing container 1, a stage (holder) 2, a shower head 3, an exhauster 4, a gas supplier 5, an RF power supplier 8, a controller 9, and the like.

The processing container 1 is made of a metal such as aluminum and has a substantially cylindrical shape. The processing container 1 accommodates a substrate W such as a wafer therein. A loading/unloading port 11 for loading or unloading the substrate W therethrough is formed in a sidewall of the processing container 1. The loading/unloading port 11 is open or closed by a gate valve 12. An annular exhaust duct 13 having a rectangular cross section is provided on a main body of the processing container 1. A slit 13a is formed in the exhaust duct 13 along an inner peripheral surface thereof. An exhaust port 13b is formed in an outer wall of the exhaust duct 13. A ceiling wall 14 is provided on an upper surface of the exhaust duct 13 to close an upper opening of the processing container 1 with an insulator member 16 interposed therebetween. A space between the exhaust duct 13 and the insulator member 16 is air-tightly sealed with a seal ring 15. A partitioning member 17 vertically partitions an interior of the processing container 1 when the stage 2 (and a cover member 22) has been raised to a processing position to be described later.

The stage 2 horizontally holds the substrate W inside the processing container 1. The stage 2 is formed in a shape of a disk having a size corresponding to the substrate W, and is supported by a supporting member 23. The stage 2 is made of a ceramic material such as AlN or a metal material such as aluminum or nickel alloy, and includes a heater 21 embedded therein to heat the substrate W. The heater 21 generates heat by being supplied with power from a heater power supply (not illustrated). And the substrate W is controlled to a predetermined temperature by controlling an output of the heater 21 in response to a temperature signal from a thermocouple (not illustrated) provided near an upper surface of the stage 2. The stage 2 is provided with the cover member 22, which is made of ceramics such as alumina, to cover an outer peripheral region of the upper surface and a side surface of the stage 2.

The supporting member 23 is provided on a bottom surface of the stage 2 to support the stage 2. The supporting member 23 passes through a hole formed in a bottom wall of the processing container 1 from the center of the bottom surface of the stage 2, and extends downward of the processing container 1. A lower end of the supporting member 23 is connected to a lifter 24. By the lifter 24, the stage 2 may move up and down via the supporting member 23 between a processing position illustrated in FIG. 1 and a transfer position indicated by a two-dot dashed line below the processing position. The substrate W may be transferred at the transfer position. A flange 25 is attached to the supporting member 23 below the processing container 1. A bellows 26 is provided between a bottom surface of the processing container 1 and the flange 25. The bellows 26 is configured to isolate an internal atmosphere of the processing container 1 from ambient air, and to be flexible with the vertical movement of the stage 2.

Three (only two are illustrated) wafer supporting pins 27 are provided near the bottom surface of the processing container 1 to protrude upward from a lifting plate 27a. The wafer supporting pins 27 are moved up and down via the lifting plate 27a by a lifting mechanism 28, which is provided below the processing container 1. The wafer supporting pins 27 are inserted into respective through-holes 2a provided in the stage 2, which is at the transfer position, thus being capable of moving up and down with respect to the upper surface of the stage 2. The substrate W is transferred between a transfer mechanism (not illustrated) and the stage 2 by moving the wafer supporting pins 27 up and down.

The shower head 3 supplies a process gas into the processing container 1 in the form of a shower. The shower head 3 is made of a metal, is provided to face the stage 2, and has approximately a same diameter as the stage 2. The shower head 3 includes a main body 31 and a shower plate 32. The main body 31 is fixed to the ceiling wall 14 of the processing container 1. The shower plate 32 is connected below the main body 31. A gas diffusion space 33 is formed between the main body 31 and the shower plate 32. A gas introduction hole 36 is provided in the gas diffusion space 33 to penetrate the ceiling wall 14 of the processing container 1 and a center of the main body 31. An annular protrusion 34 is formed on the periphery of the shower plate 32 to protrude downward. Gas discharge holes 35 are formed in an inner flat portion of the annular protrusion 34. In a state where the stage 2 is present at the processing position, a processing space 38 is created between the stage 2 and the shower plate 32, and an upper surface of the cover member 22 and the annular protrusion 34 are close to each other to create an annular gap 39.

The exhauster 4 is used to exhaust the interior of the processing container 1. The exhauster 4 includes an exhaust pipe 41 connected to the exhaust port 13b and an exhaust mechanism 42 connected to the exhaust pipe 41 and having a vacuum pump, a pressure control valve, and the like. During processing, a gas inside the processing container 1 reaches the exhaust duct 13 via the slit 13a, and is exhausted from the exhaust duct 13 via the exhaust pipe 41 by the exhaust mechanism 42.

The gas supplier 5 is used to supply various process gases to the shower head 3. The gas supplier 5 includes a gas source 51 and a gas line 52. The gas source 51 includes, for example, a source of various process gases, a mass flow controller, and a valve (none of which is illustrated). Various process gases are introduced from the gas source 51 into the gas diffusion space 33 via the gas line 52 and the gas introduction hole 36.

Further, the film forming apparatus is a capacitively coupled plasma apparatus, the stage 2 functions as a lower electrode, and the shower head 3 functions as an upper electrode. The stage 2 is grounded via a condenser (not illustrated). However, for example, the stage 2 may be grounded without a condenser, or may be grounded via a circuit in which a condenser and a coil are combined with each other. The shower head 3 is connected to the RF power supplier 8.

The RF power supplier 8 supplies radio-frequency power (hereinafter also referred to as “RF power”) to the shower head 3. The RF power supplier 8 includes an RF power supply 81, a matcher 82, and a feed line 83. The RF power supply 81 is a power supply configured to generate the RF power. The RF power has a frequency suitable for plasma generation. A frequency of the RF power ranges, for example, from 450 KHz in a low frequency band to 2.45 GHz in a microwave band. The RF power supply 81 is connected to the main body 31 of the shower head 3 via the matcher 82 and the feed line 83. The matcher 82 includes a circuit for matching a load impedance to an internal impedance of the RF power supply 81. In addition, although the RF power supplier 8 has been described as supplying the RF power to the shower head 3 serving as the upper electrode, it is not limited thereto. The RF power supplier 8 may be configured to supply the RF power to the stage 2 serving as the lower electrode.

The controller 9 is, for example, a computer, and includes a central processing unit (CPU), a random access memory (RAM), a read only memory (ROM), an auxiliary storage device, and the like. The CPU operates based on a program stored in the ROM or the auxiliary storage device, and controls an operation of the film forming apparatus. The controller 9 may be provided inside or outside the film forming apparatus. When the controller 9 is provided outside the film forming apparatus, the controller 9 may control the film forming apparatus via, for example, a wired or wireless communication line.

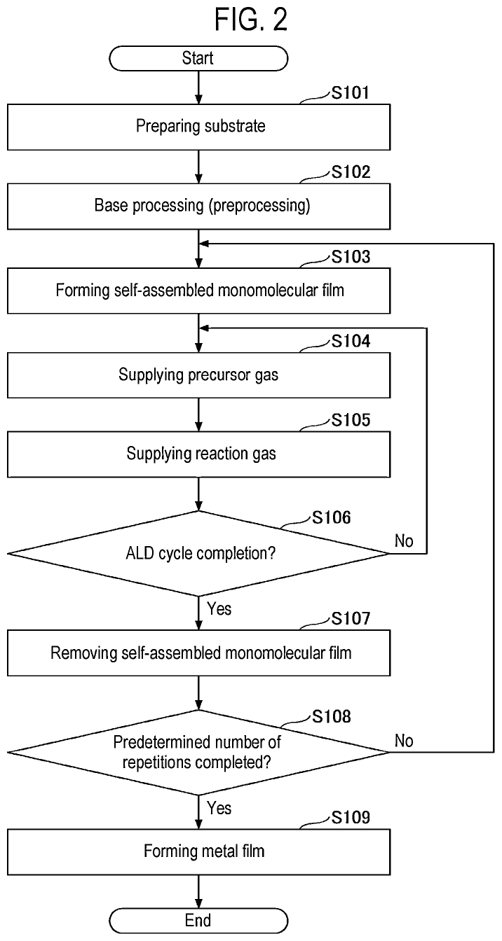

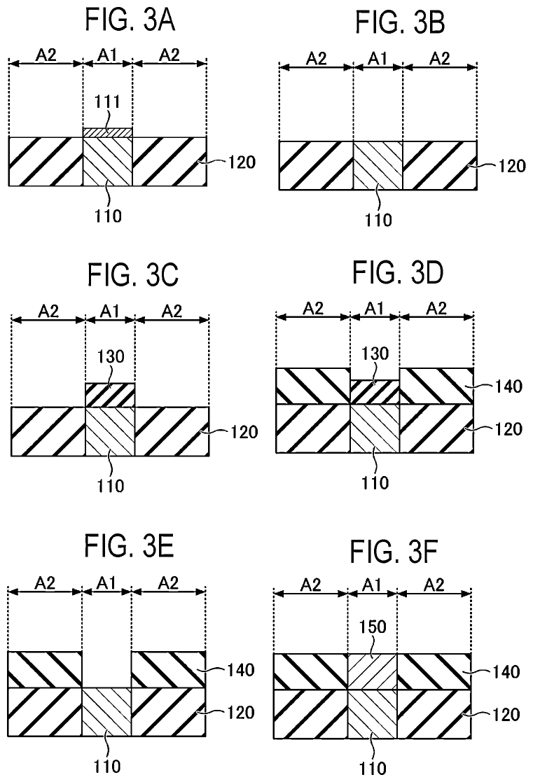

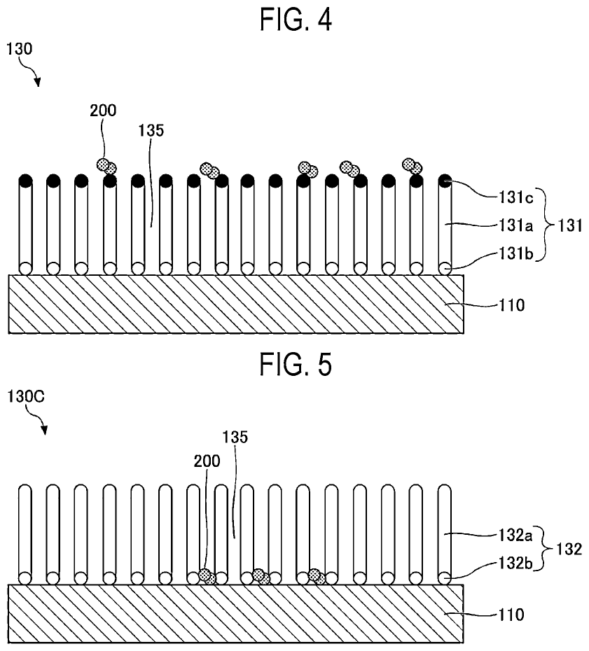

Next, an example of a film forming method according to an embodiment will be described with reference to FIGS. 2 and 3A to 3F. FIG. 2 is a flowchart illustrating an example of the film forming method. FIGS. 3A to 3F are examples of cross-sectional schematic diagrams illustrating a state of the substrate W in each operation.

In step S101, the controller 9 prepares the substrate W. Here, an example of a cross-sectional schematic diagram of the prepared substrate W is illustrated in FIG. 3A. The substrate W has a first area A1 and a second area A2. A metal film 110 is formed in the first area A1. The metal film 110 is, for example, a conductive film such as a copper (Cu) film or a ruthenium (Ru) film. Further, a native oxide film 111 is formed on a surface of the metal film 110. An insulating film such as a first insulating film 120 is formed in the second area A2. The first insulating film 120 is made of an insulating material containing, for example, silicon (Si), and is, for example, silicon oxide, silicon nitride, silicon oxynitride, silicon carbide, silicon oxycarbide, or silicon oxycarbonitride. The controller 9 controls the lifter 24 to move the stage 2 down toward the transfer position. In this state, the controller 9 opens the gate valve 12. Subsequently, the controller 9 controls a transfer arm (not illustrated) to load the substrate W into the processing container 1 via the loading/unloading port 11, and place the substrate W on the stage 2, which has been heated to a predetermined temperature (e.g., 600 degrees C. or lower) by the heater 21. Subsequently, the controller 9 controls the lifter 24 to move the stage 2 up to the processing position, and depressurizes the interior of the processing container 1 to a predetermined degree of vacuum by the exhaust mechanism 42.

In step S102, the controller 9 performs a base processing (preprocessing) for the formation of a self-assembled monolayer 130 or the formation of a second insulating film 140, which will be described later. The base processing in step S102 may include removal of the native oxide film formed on a surface of the substrate W or removal of contaminants. Further, the base processing may include a surface modification processing after the removal of the native oxide film formed on the surface of the substrate W or the removal of contaminants. For example, in step S102, the controller 9 performs a processing of removing the native oxide film 111 from the substrate W. For example, this processing may be done by supplying a reducing gas (e.g., hydrogen, alcohol, and the like) into the processing container 1 and heating the substrate W to, for example, 200 degrees C. to remove the native oxide film 111 formed on the surface of the metal film 110. Consequently, as illustrated in FIG. 3B, the native oxide film 111 is removed from the surface of the metal film 110.

In step S103, the controller 9 forms the self-assembled monolayer 130. For example, a gas of organic compounds 131 (see FIG. 4 to be described later) is supplied into the processing container 1. The organic compound 131 includes a main chain (chain portion) 131a, a first functional group 131b formed at one end of the main chain 131a, and a second functional group 131c formed at the other end of the main chain 131a.

The main chain 131a is formed by linking carbon (C) atoms. The main chain 131a is formed of, for example, an alkyl chain.

The first functional group 131b is a functional group which selectively adsorbs (binds) to the metal film 110. The first functional group 131b includes, for example, at least one selected from a group consisting of thiol, carboxylic acid, sulfonic acid, phosphoric acid, and olefin.

The second functional group 131c is a functional group which adsorbs (binds) a precursor gas to be described later. Further, the second functional group 131c is a functional group that has equal or lower adsorption to the metal film 110 compared to the first functional group 131b. The second functional group 131c may be a functional group containing oxygen (O). When the functional group contains oxygen (O), the second functional group 131c may include at least one selected from a group consisting of alcohol, carboxylic acid, and ester. Further, the second functional group 131c may be a functional group containing sulfur(S). When the functional group contains sulfur(S), the second functional group 131c may include at least one selected from a group consisting of thiol, thioester, sulfonic acid, and the like. Further, the first functional group 131b and the second functional group 131c may also be the same functional group.

Thus, as illustrated in FIG. 4 to be described later, the first functional group 131b of the organic compound 131 adsorbs to the surface of the metal film 110, and the organic compounds 131 are oriented by interactions between the organic compounds 131, thereby forming the self-assembled monolayer (SAM) 130. Consequently, as illustrated in FIG. 3C, the self-assembled monolayer 130 is formed on the surface of the metal film 110. Further, as illustrated in FIG. 4, the first functional group 131b of the organic compound 131 is arranged at an interface between the metal film 110 and the self-assembled monolayer 130, and the second functional group 131c of the organic compound 131 is arranged at a surface of the self-assembled monolayer 130.

On the other hand, the adsorption of the first functional group 131b and the second functional group 131c of the organic compound 131 to the first insulating film 120 (and the second insulating film 140 to be described later) is prevented. This allows the self-assembled monolayer 130 to be selectively formed on the metal film 110.

In addition, the main chain 131a of the organic compound 131 may be an alkyl chain and the number (n) of carbon atoms in the alkyl chain may be 30 or less (n≤30). When the main chain 131a of the organic compound 131 is too long, the main chain 131a may be bent, causing both the first functional group 131b and the second functional group 131c to adsorb to the surface of the metal film 110. In contrast, by setting the number (n) of carbon atoms in the alkyl chain to 30 or less, the first functional group 131b adsorbs to the surface of the metal film 110, while the second functional group 131c does not absorb to the surface of the metal film 110. This makes it possible to orient the organic compounds 131 by interactions between the organic compounds 131, and appropriately form the self-assembled monolayer 130.

Further, more preferably, the main chain 131a of the organic compound 131 may be an alkyl chain and the number (n) of carbon atoms of the alkyl chain may be 10 or less (n≤ 10). Since this allows the second functional group 131c of the organic compound 131 to appear closer to the surface of the metal film 110, the trapping of TMA molecules 200 (see FIG. 4 to be described later) used as a precursor gas can be promoted.

Subsequently, the controller 9 forms the second insulating film 140 on the first insulating film 120 in the second area A2 by an atomic layer deposition (ALD) process (steps S104 to S106).

In step S104, the controller 9 supplies a precursor gas for the second insulating film 140. Here, a trimethyl aluminum (TMA) gas is supplied as the precursor gas for the second insulating film 140. Thus, TMA adsorbs to the surface of the first insulating film 120 in the second area A2 to form an adsorption layer. Meanwhile, the self-assembled monolayer 130 is formed on the metal film 110 in the first area A1, which prevents the precursor gas from adsorbing to the surface of the metal film 110. In other words, the self-assembled monolayer 130 formed on the metal film 110 functions as a blocking film which blocks the adsorption of the precursor gas on the metal film 110.

Subsequently, in step S105, the controller 9 supplies a reaction gas which reacts with the precursor for the second insulating film 140. Here, a H₂O gas is supplied as the reaction gas for the second insulating film 140. Thus, the TMA adsorbed to the surface of the first insulating film 120 reacts with the reaction gas to form an AlO layer (Al₂O₃ layer) in the second area A2.

Subsequently, in step S106, the controller 9 determines whether or not a predetermined number of cycles, each cycle including the operations of steps S301 and S302, has been repeated (ALD cycle completion?). When the predetermined number of cycles has not been repeated (NO in S106), the controller 9 returns to step S104. When the predetermined number of cycles has been repeated (YES in S106), the controller 9 proceeds to step S107.

In this way, the operation of supplying the precursor gas for the second insulating film 140 (S104) and the operation of supplying the reaction gas for the second insulating film 140 (S105) are repeated multiple times as one ALD cycle (S106). Consequently, as illustrated in FIG. 3D, an AlO film is formed on the first insulating film 120 in the second area A2 by an ALD process, and the second insulating film 140 is formed. Further, the self-assembled monolayer 130 formed on the metal film 110 functions as a blocking film which blocks the formation of the second insulating film 140 on the metal film 110.

In step S107, the controller 9 removes the self-assembled monolayer 130 by etching. Consequently, as illustrated in FIG. 3E, the self-assembled monolayer 130 formed in the first area A1 is removed.

In step S108, the controller 9 determines whether or not a predetermined number of repetitions has been completed. When the predetermined number of repetitions has not been completed (NO in S108), the controller 9 returns to step S103. When the predetermined number of repetitions has been completed (YES in S108), the controller 9 proceeds to step S109.

Thus, by repeating the formation of the self-assembled monolayer 130 in the first area A1 (S103), the formation of the second insulating film 140 in the second area A2 (S104 to S106), and the removal of the self-assembled monolayer 130 in the first area A1 (S107), the second insulating film 140 may be selectively formed in the second area A2.

In step S109, the controller 9 forms a metal film 150. Consequently, as illustrated in FIG. 3F, the metal film 150 is formed on the metal film 110 in the first area A1.

Next, the self-assembled monomolecular film will be further described with reference to FIGS. 4 and 5. FIG. 4 is an example of a cross-sectional schematic diagram illustrating the self-assembled monolayer 130 according to the embodiment. FIG. 5 is an example of a cross-sectional schematic diagram illustrating a self-assembled monolayer 130C according to Reference Example.

Here, in a film forming method according to Reference Example, a gas different from the organic compound gas supplied when forming the self-assembled monolayer 130 in step S103 is supplied. Specifically, as illustrated in FIG. 5, the controller 9 supplies a gas of organic compounds 132 into the processing container 1 to form the self-assembled monolayer 130C. The gas of the organic compounds 132 has a main chain 132a and a functional group 132b. Here, the main chain 132a is formed by linking carbon (C) atoms. The functional group 132b is a functional group which selectively adsorbs to the metal film 110. Other configurations are similar to those of the film forming method according to the embodiment illustrated in FIG. 2.

In the film forming method according to Reference Example, as illustrated in FIG. 5, the functional group 132b of the organic compound 132 adsorbs to the surface of the metal film 110, and the organic compounds 132 are oriented by interactions between the organic compounds, thereby forming the self-assembled monolayer 130C. Here, the self-assembled monolayer 130C has voids 135 between the organic compounds 132. Therefore, the TMA molecules 200 as the precursor gas may penetrate the self-assembled monolayer 130C via the voids 135, and reach the surface of the metal film 110 (the interface between the metal film 110 and the self-assembled monolayer 130C), so that the TMA molecules 200 may adsorb to the surface of the metal film 110. Further, since the precursor gas (TMA) has high reactivity, when the cycle of the ALD process (steps S104 to S106) is repeated, an AlO film may be formed at an interface between the metal film 110 and the self-assembled monolayer 130C, starting from the TMA molecules 200 adsorbed to the surface of the metal film 110 (to the interface between the metal film 110 and the self-assembled monolayer 130C). Further, the AlO film formed at the interface between the metal film 110 and the self-assembled monolayer 130C may remain on the surface of the metal film 110 even after the self-assembled monolayer 130C is removed (step S107). This may reduce the selectivity of the formation of the second insulating film 140.

In contrast, in the film forming method according to the embodiment, as illustrated in FIG. 4, the first functional group 131b of the organic compound 131 adsorbs to the surface of the metal film 110, and the organic compounds 132 are oriented by the interactions between the organic compounds, thereby forming the self-assembled monolayer 130. Here, the self-assembled monolayer 130 has voids 135 between the organic compounds 132. Here, the second functional group 131c of the organic compound 131 is arranged at upper sides of the voids 135 (near the surface of the self-assembled monolayer 130). As a result, the TMA molecules 200 as the precursor gas adsorb to and are trapped by the second functional group 131c before they enter the voids 135 and reach the interface between the metal film 110 and the self-assembled monolayer 130C. This prevents the TMA molecules 200 as the precursor gas from penetrating the self-assembled monolayer 130C via the voids 135. Further, this prevents the TMA molecules 200 from adsorbing to the interface between the metal film 110 and the self-assembled monolayer 130. Further, this prevents the formation of an AlO film at the interface between the metal film 110 and the self-assembled monolayer 130. Further, in the film forming method according to the embodiment, an AlO film is formed on the surface of the self-assembled monolayer 130, starting from the TMA molecules 200 trapped by the second functional group 131c. However, an amount of the AlO film formed on the self-assembled monolayer 130 in the first area A1 is smaller than that of the second insulating film 140 formed on the first insulating film 120 in the second area A2. Therefore, the AlO film formed on the surface of the self-assembled monolayer 130 is removed along with the self-assembled monolayer 130 from the first area A1 when removing the self-assembled monolayer 130 (S107). This makes it possible to selectively form the second insulating film 140 in the second area A2. In other words, the selectivity in the formation of the second insulating film 140 may be improved.

Further, in the film forming method according to the embodiment, the formation of the self-assembled monolayer 130 (S103), the formation of the second insulating film 140 (S104 to S106), and the removal of the self-assembled monolayer 130 (S107) are repeated. This makes it possible to remove the AlO film formed on the surface of the self-assembled monolayer 130 in the first area A1, which improves the selectivity in the formation of the second insulating film 140.

In addition, although trimethyl aluminum (TMA) was used as an example of the precursor gas, the precursor gas is not limited thereto. The precursor gas may include at least one selected from a group consisting of trialkyl aluminum, aluminum trihalide, and alkoxide.

It should be noted that the embodiments disclosed herein are exemplary in all respects and are not restrictive. The above-described embodiments may be omitted, replaced or modified in various forms without departing from the scope and spirit of the appended claims.

Further, this application claims priority based on Japanese Patent Application No. 2022-71107 filed on Apr. 22, 2022, and the entire contents of this Japanese patent application is incorporated herein by reference.

### EXPLANATION OF REFERENCE NUMERALS

W: substrate, 1: processing container, 2: stage (holder), 3: shower head, 4: exhauster, 5: gas supplier, 8: RF power supplier, 9: controller, 110: metal film, 111: native oxide film, 120: first insulating film, 130: self-assembled monolayer, 131: organic compound, 131a: main chain, 131b: first functional group, 131c: second functional group, 140: second insulating film, 150: metal film

What is claimed is:

1. A film forming method, comprising:
preparing a substrate having a metal film formed on a surface of a first area and a first insulating film formed on a surface of a second area;
forming a self-assembled monolayer of an organic compound in the first area by supplying, to a surface of the substrate, a gas containing the organic compound having a chain portion, a first functional group provided at one end of the chain portion, and a second functional group provided at a remaining end of the chain portion;
forming a second insulating film in the second area by supplying a precursor gas and a reaction gas to the surface of the substrate; and
removing the self-assembled monolayer formed in the first area.

2. The film forming method of claim 1, wherein the first functional group is a functional group which selectively adsorbs to the metal film, and
wherein the second functional group is a functional group which selectively adsorbs to the precursor gas.

3. The film forming method of claim 1, wherein the first functional group includes at least one selected from a group consisting of thiol, carboxylic acid, sulfonic acid, phosphoric acid, and olefin.

4. The film forming method of claim 1, wherein the second functional group includes at least one selected from a group consisting of alcohol, carboxylic acid, and ester.

5. The film forming method of claim 1, wherein the second functional group includes at least one selected from a group consisting of thiol, thioester, and sulfonic acid.

6. The film forming method of claim 1, wherein the precursor gas includes at least one selected from a group consisting of trimethyl aluminum, trialkyl aluminum, aluminum trihalide, and alkoxide.

7. The film forming method of claim 1, wherein the chain portion is an alkyl chain, and a number of carbon atoms in the alkyl chain is 30 or less.

8. The film forming method of claim 7, wherein the number of carbon atoms in the alkyl chain is 10 or less.

9. The film forming method of claim 1, wherein the forming the second insulating film in the second area includes repeating a cycle including:
supplying the precursor gas to the surface of the substrate such that the precursor gas is adsorbed to a surface of the first insulating film in the second area and to the second function group on a surface of the self-assembled monolayer in the first area; and
supplying the reaction gas to the surface of the substrate such that the reaction gas reacts with the precursor gas.

10. The film forming method of claim 1, wherein the forming the self-assembled monolayer in the first area, the forming the second insulating film in the second area, and the removing the self-assembled monolayer formed in the first area are repeated.

11. A substrate processing apparatus, comprising:
a holder configured to hold a substrate;
a processing container in which the holder is accommodated;
a gas supplier configured to supply a gas to the processing container; and
a controller,
wherein the controller is configured to execute a process including:
holding, by the holder, the substrate having a metal film formed on a surface of a first area and a first insulating film formed on a surface of a second area;
forming a self-assembled monolayer of an organic compound in the first area by supplying, to a surface of the substrate, a gas containing the organic compound having a chain portion, a first functional group provided at one end of the chain portion, and a second functional group provided at a remaining end of the chain portion;
forming a second insulating film in the second area by supplying a precursor gas and a reaction gas to the surface of the substrate; and
removing the self-assembled monolayer formed in the first area.
